(19) United States
(12) Patent Application Publication
(10) Pub. No.: US 2003/0155605 A1
(43) Pub. Date: Aug. 21, 2003

(54) EEPROM memory cell with high radiation resistance

(75) Inventors: Fuh-Cheng Jong, Tainan (TW); Kent Kuohua Chang, Taipei (TW)

Correspondence Address: LOWE HAUPTMAN GILMAN & BERNER, LLP, Suite 310, 1700 Diagonal Road, Alexandria, VA, 22314, US

(73) Assignee: Macronix International Co., Ltd.

(21) Appl. No.: 10/075,251

(22) Filed: Feb. 15, 2002

(51) Int. Cl. H01L 29/06

(52) U.S. Cl. 257/314

(57) ABSTRACT

An EEPROM memory cell with high radiation resistance is provided. The present EEPROM memory cell comprises a semiconductor substrate of a first conductivity, a source having a region of the semiconductor substrate doped to have a second conductivity opposite to the first conductivity, a drain spaced from the source and having a region of the semiconductor substrate doped to have the second conductivity, a channel formed in the space between the source and the drain within the semiconductor substrate, a first oxide layer with a first thickness overlying and covering the channel of the semiconductor substrate, a conducting charge trapping layer formed on the first oxide layer, a second oxide layer with a second thickness more than the first thickness of the first oxide layer, overlying and covering the conducting charge trapping layer and a conducting gate layer formed on the second oxide layer.

### BACKGROUND OF THE INVENTION

1. Field of the Invention

The present invention relates in general to a nonvolatile memory cell, and more particularly to a floating gate electrically erasable and programmable read only memory (EEPROM) cell.

2. Description of the Prior Art

Since the very beginning of nonvolatile memories development, various methods to achieve in-system electrical erasure, thus obtaining an electrically erasable programmable read only memory (EEPROM), were developed.

In 1967 Wegener et al. introduced a MNOS cell. The MNOS cell resembles a standard MOS transistor in which the oxide has been replaced by a nitride-oxide stacked layer. Electrons and holes can be trapped in the nitride, which then behaves as a charge storage element. Programming is achieved by applying a high, positive bias V_{G} to the gate, thus inducing the quantum-mechanical tunneling of electrons from the channel region into the nitride traps. Erasure is obtained by tunneling of holes from the semiconductor to the nitride traps when V_{G} is negative and sufficiently high.

In order to improve the charge retention of MNOS memories, new structures have been developed. The SNOS (silicon-nitride-oxide-semiconductor) employs a nitride layer deposited by low pressure chemical vapor deposition (LPCVD) and a hydrogen anneal which improves the quality of the interfaces. The retention of the SNOS improves as the thickness of the nitride is reduced; unfortunately this leads to enhanced hole injection from the gate. In order to eliminate this problem, a top oxide layer is used between the gate and the nitride layer, thus obtaining the SONOS (silicon-oxide-nitride-oxide-semiconductor) structure. SONOS EEPROM has been reported to withstand erasure/write cycling up to 10M cycles, with 1.0 μm² cells suitable for 256 MB memory arrays.

In order to obtain an electrically erasable and programmable nonvolatile memory, a floating gate EEPROM cell, which adopts Fowler-Nordheim tunneling effect for both programming and erasing, is developed. FIG. 1 shows a schematic cross-sectional view of the prior floating gate EEPROM cell. The floating gate EEPROM cell of FIG. 1 includes a pair of spaced-apart heavily doped N-type semiconductor region 11 and 12 forming the respective source and drain regions of the memory cell. A lightly doped P-type semiconductor region 13 defines the channel region of the cell transistor which is disposed between the source and drain regions 11 and 12. Formed above the channel region 13 is a lower silicon dioxide layer 14. Formed above the lower silicon dioxide layer 14 is a floating gate formed of polysilicon 15, which provides the mechanism for trapping electrical charges therein and forming the memory element of the cell. Formed over the floating gate of polysilicon 15 is a top silicon dioxide layer 16. The top silicon dioxide layer 16 functions to electrically isolate a control gate of polysilicon 17 from the underlying floating gate 15. Programming is obtained by applying a high voltage to the control gate 17, with the drain region 12 at low bias. By capacitive coupling, the voltage on the floating gate 15 is also increased, and tunneling of electrons from the drain region 12 to the floating gate 15 is initiated through the lower silicon dioxide layer 14. Erasing occurs when the drain region 12 is raised to a high voltage, and the control gate 17 is grounded; the floating gate 15 is capacitively coupled to a low voltage, and electrons tunnel from the floating gate 15 into the drain region 12.

The “0” state represents excess electrons stored in the floating gate 15 (high threshold state). The “1” state represents either the lack of electrons or excess holes stored on the floating gate 15. When the floating gate EEPROM cell in the “0” state of FIG. 1 is exposed in radiation environment, the radiation imparts energy to the lower silicon dioxide layer 14 and top silicon dioxide layer 16, and electron-hole pairs are generated therein. The electrons quickly drift toward the control gate 17 and the semiconductor substrate 10 under the influence of the oxide electric fields. The holes are injected into the floating gate 15, reducing the net amount of electron charges stored in the floating gate 15, and decreasing the threshold voltage of the memory transistor. Hence, when the floating gate EEPROM cell of FIG. 1 is exposed in the radiation environment, the radiation results in decay of the “0” state and causing retention failure of the “0” state.

Accordingly, it is an intention to provide an improved structure of EEPROM memory cell, which can overcome the problem of retention failure of the prior EEPROM cell and thus improve the characteristic of data retention of a nonvolatile memory cell.

### SUMMARY OF THE INVENTION

It is an objective of the present invention to provide an EEPROM memory cell with high radiation resistance, which can resolve the problem of retention failure encountered in the conventional EPROM (electrically programmable read only memory) and EEPROM (electrically erasable and programmable read only memory) devices when exposed in radiation environment.

It is anther objective of the present invention to provide an EEPROM memory cell with high radiation resistance, which provides a manufacturing process simpler than the processes for manufacturing the conventional non-volatile memory devices.

In order to achieve the above objectives, the present invention provides an EEPROM memory cell with high radiation resistance. The present EEPROM memory cell comprises a semiconductor substrate of a first conductivity, a source having a region of the semiconductor substrate doped to have a second conductivity opposite to the first conductivity, a drain spaced from the source and having a region of the semiconductor substrate doped to have the second conductivity, a channel formed in the space between the source and the drain within the semiconductor substrate, a first oxide layer with a first thickness overlying and covering the channel of the semiconductor substrate, a conducting charge trapping layer formed on the first oxide layer, a second oxide layer with a second thickness more than the first thickness of the first oxide layer, overlying and covering the conducting charge trapping layer and a conducting gate layer formed on the second oxide layer. The threshold voltage of the present EEPROM memory cell is increased as the second thickness of the second oxide layer increases, while is less shifted as the first thickness of the first oxide layer decreases. The larger the initial “0” state threshold voltage, the larger the radiation dose necessary for a retention failure. Therefore, a non-volatile memory cell with high radiation resistance can be provided by the present invention.

### BRIEF DESCRIPTION OF THE DRAWINGS

The above and other objects, features and advantages of the present invention will be apparent from the following description with reference to accompanying drawings:

FIG. 1 is a schematically cross-sectional view of a prior EEPROM memory cell; and

FIG. 2 is a schematically cross-sectional view of an EEPROM memory cell of the present invention.

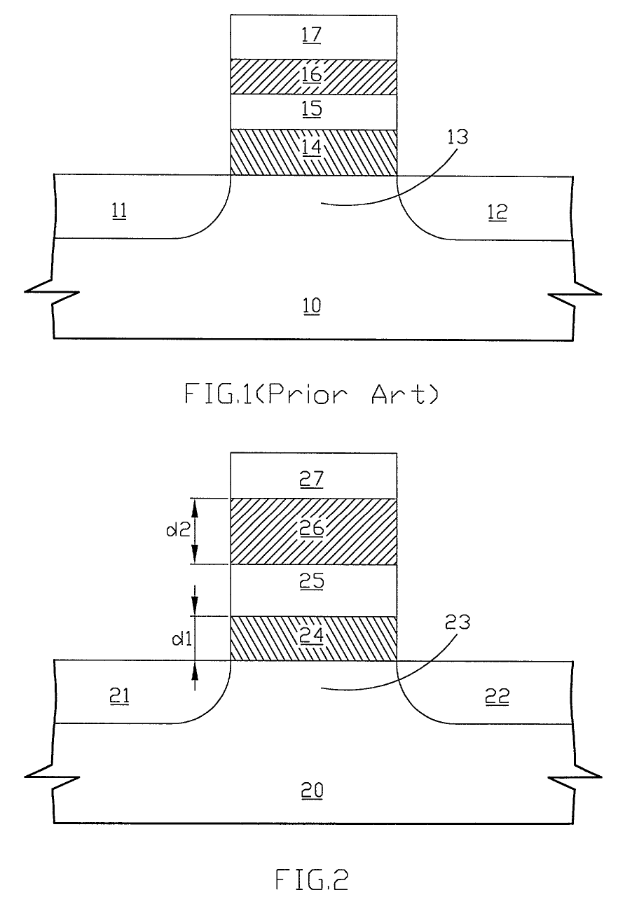

### DESCRIPTION OF THE PREFERRED EMBODIMENT

The present invention provides an EEPROM memory cell with high radiation resistance, which is a kind of floating gate EEPROM memory cell with high floating gate radiation hardness. FIG. 2 is a schematic cross-sectional view of the present floating gate EEPROM memory cell, which comprises a semiconductor substrate 20 of a first conductivity, a source 21 having a region of the semiconductor substrate 20 doped to have a second conductivity opposite to the first conductivity, a drain 22 spaced from the source 21 and having a region of the semiconductor substrate 20 doped to have the second conductivity, a channel 23 formed in the space between the source 21 and the drain 22 within the semiconductor substrate 20, a first oxide layer 24 with a first thickness d₁ overlying and covering the channel 23 of the semiconductor substrate 20, a conducting charge trapping layer 25 (called floating gate) formed on and overlying the first oxide layer 24, a second oxide layer 26 with a second thickness d₂ more than the first thickness d₁ of the first oxide layer 24, overlying and covering the conducting charge trapping layer 25, and a conducting gate layer 27 (called control gate) formed on and overlying the second oxide layer 26.

The programming and erasing mechanisms of the present floating gate EEPROM memory cell are similar to those of the conventional floating gate EEPROM memory cell. Therefore, they are not described and explained herein again. The threshold voltage Vₜₕ of the present floating gate EEPROM memory cell as shown in FIG. 2 is directly related to the electron charges stored in the floating gate 25. The threshold voltage may be written as formula (I)

$${V}_{th} = {V}_{si} + \frac{{σ}_{fg} {d}_{2}}{{ϵ}_{2}} \qquad ( I )$$

where Vₛᵢ is the threshold of the memory transistor due to processing and is a function of many variables including d₁ and d₂. d₁ is the oxide thickness between the floating gate 25 and the semiconductor substrate 20, d₂ is the oxide thickness between the control gate 27 and the floating gate 25, while ε₂ is the permittivity for the second oxide layer 26. σ_{fg} is the net electron charges per unit area stored in the floating gate 25. The threshold voltage Vₜₕ is increased as the thickness of d₂ is increased. While, when the thickness d₁ is reduced, there will be less electron-hole pairs generated in the first oxide layer 24 between the floating gate 25 and the semiconductor substrate 20. The amount of charges in the floating gate 25 is less altered, thus causing less shift of threshold voltage Vₜₕ.

Accordingly, for the present floating gate EEPROM memory cell, the thicker the second oxide layer 26 and the thinner the first oxide layer 24, the larger the threshold voltage Vₜₕ of the present floating gate EEPROM memory cell. Moreover, the larger the initial “0” state threshold voltage Vₜₕ, the larger the radiation dose necessary for a retention failure. Thus, according to the structure of the EEPROM memory cell provided by the present invention, an EEPROM memory cell with high floating gate radiation hardness can be obtained.

A floating gate EEPROM memory cell according to one preferred embodiment of the present invention is illustrated below. The floating gate EEPROM memory cell according to the preferred embodiment comprises a P type silicon substrate, a source having a region of the silicon substrate doped to have N type conductivity, a drain spaced from the source and having a region of the silicon substrate doped to have N type conductivity, a channel formed in the space between the source and the drain within the silicon substrate, a first silicon dioxide layer with a first thickness overlying and covering the channel of the silicon substrate, a conducting charge trapping layer of polysilicon (called floating gate) formed on the first silicon dioxide layer, a second silicon dioxide layer with a second thickness more than the first thickness of the first silicon dioxide layer, overlying and covering the conducting charge trapping layer of polysilicon, and a conducting gate layer of polysilicon (called control gate) formed on the second silicon dioxide layer.

The preferred embodiment is only used to illustrate the present invention, not intended to limit the scope thereof. Many modifications of the preferred embodiment can be made without departing from the spirit of the present invention.

What is claimed is:

1. An EEPROM memory cell with high radiation resistance, comprising:
a semiconductor substrate of a first conductivity;
a source having a region of said semiconductor substrate doped to have a second conductivity opposite to said first conductivity;
a drain spaced from said source and having a region of said semiconductor substrate doped to have said second conductivity;
a channel formed in the space between said source and said drain within said semiconductor substrate;
a first oxide layer with a first thickness overlying and covering said channel of said semiconductor substrate;
a conducting charge trapping layer formed on and overlying said first oxide layer;
a second oxide layer with a second thickness more than the first thickness of said first oxide layer, overlying and covering said conducting charge trapping layer; and
a conducting gate layer formed on and overlying said second oxide layer.

2. The EEPROM memory cell of claim 1, wherein said semiconductor substrate comprises a silicon substrate.

3. The EEPROM memory cell of claim 1, wherein said first oxide layer comprises a silicon dioxide layer.

4. The EEPROM memory cell of claim 1, wherein said second oxide layer comprises a silicon dioxide layer.

5. The EEPROM memory cell of claim 1, wherein said conducting charge trapping layer comprises polysilicon.

6. The EEPROM memory cell of claim 1, wherein said conducting gate layer comprises polysilicon.

7. A floating gate EEPROM memory cell with high radiation resistance, comprising:
a P type silicon substrate;
a source having a region of said silicon substrate doped to have an N conductivity;
a drain spaced from said source and having a region of said silicon substrate doped to have an N conductivity;
a channel formed in the space between said source and said drain within said silicon substrate;
a first silicon dioxide layer with a first thickness overlying and covering said channel of said silicon substrate;
a floating gate of polysilicon formed on and overlying said first silicon dioxide layer;
a second silicon dioxide layer with a second thickness more than the first thickness of said first silicon dioxide layer, overlying and covering said floating gate; and
a control gate of polysilicon formed on and overlying said second silicon dioxide layer.
